(19) United States
(12) Patent Application Publication
(10) Pub. No.: US 2025/0051540 A1
(43) Pub. Date: Feb. 13, 2025

(54) CURABLE COMPOSITION FOR FORMING LOW REFRACTIVE INDEX FILM, LOW REFRACTIVE INDEX FILM, OPTICAL DEVICE, AND METHOD FOR PRODUCING LOW REFRACTIVE INDEX FILM

(71) Applicant: TOKYO OHKA KOGYO CO., LTD., Kanagawa (JP)

(72) Inventors: Yohei AOYAMA, Kanagawa (JP); Kenri KONNO, Kanagawa (JP); Risako MORI, Kanagawa (JP)

(21) Appl. No.: 18/795,579

(22) Filed: Aug. 6, 2024

(30) Foreign Application Priority Data
Aug. 8, 2023 (JP) 2023-129217

(51) Int. Cl. C08K 3/36; C08F 222/10

(52) U.S. Cl. CPC C08K 3/36; C08F 222/1006; C08F 222/1063

(57) ABSTRACT

To provide a curable composition for forming a low refractive index film of which a cured film excellent in heat resistance can be formed. A curable composition for forming a low refractive index film containing a hollow filler (A), a polymerizable compound (B), and a polymerization initiator (C), and not containing an alkali-soluble resin. The polymerizable compound (B) includes a compound (B1) having 5 or more polymerizable functional groups and a compound (B2) having 1 or more and 3 or less polymerizable functional groups. A ratio (B1/B2) of a mass of the compound (B1) to a mass of the compound (B2) is 0.25 or more and 3 or less.

This application is based on and claims the benefit of priority from Japanese Patent Application No. 2023-129217, filed on 8 Aug. 2023, the content of which is incorporated herein by reference.

### BACKGROUND OF THE INVENTION

### Field of the Invention

The present invention relates to a curable composition for forming a low refractive index film, a low refractive index film, an optical device, and a method for producing a low refractive index film.

### Related Art

A low refractive index film is used in an optical member as an optical functional film included in an antireflection film, a reflective film, a semi-transmissive semi-reflective film, a visible light reflective infrared transmissive film, an infrared reflective visible light transmissive film, a blue reflective film, a green reflective film, a red reflective film, a bright line cut filter, a color tone correction film, and the like (see Patent document 1).
Patent Document 1: Japanese Unexamined Patent Application, Publication No. 2009-271444

### SUMMARY OF THE INVENTION

In a production process of an optical member, heat treatment such as solder reflow and post-baking may be carried out. Therefore, a low refractive index film is required to have heat resistance, but this point has not been sufficiently studied.

The present invention has been made in view of the above circumstances, and has an object to provide a curable composition for forming a low refractive index film from which a cured film having excellent heat resistance can be formed, a low refractive index film including a cured product of the curable composition, an optical device including the low refractive index film, and a method for producing a low refractive index film using the curable composition.

In order to solve the above-mentioned problem, the inventors of the present invention have extensively studied, and as a result, they have found that the above-mentioned problem can be solved by a curable composition containing a hollow filler (A), a polymerizable compound (B), and a polymerization initiator (C), and not containing an alkali-soluble resin, in which a ratio (B1/B2) of a mass of a compound (B1) having 5 or more polymerizable functional groups to a mass of a compound (B2) having 1 or more and 3 or less polymerizable functional groups is 0.25 or more and 3 or less, and have completed the present invention. Specifically, the present invention provides the following.

A first aspect of the present invention relates to a curable composition for forming a low refractive index film, the composition including a hollow filler (A), a polymerizable compound (B), and a polymerization initiator (C), and not including an alkali-soluble resin,
the polymerizable compound (B) including a compound (B1) having 5 or more polymerizable functional groups and a compound (B2) having 1 or more and 3 or less polymerizable functional groups,
a ratio (B1/B2) of a mass of the compound (B1) to a mass of the compound (B2) being 0.25 or more and 3 or less.

A second aspect of the present invention relates to the curable composition for forming a low refractive index film as describe in the first aspect, in which
the compound (B1) is a compound having 5 or 6 polymerizable functional groups, and
the compound (B2) is a compound having 3 polymerizable functional groups.

A third aspect of the present invention relates to the curable composition for forming a low refractive index film as described in the first or second aspect, in which a ratio (B1/B2) of a mass of the compound (B1) to a mass of the compound (B2) is 1.25 or more and 2 or less.

A fourth aspect of the present invention relates to the curable composition for forming a low refractive index film as described in any one of the first to third aspects, in which the composition further including a surfactant (D).

A fifth aspect of the present invention relates to the curable composition for forming a low refractive index film as described in the fourth aspect, in which the surfactant (D) includes a fluorine-based surfactant and/or a silicon-based surfactant.

A sixth aspect of the present invention relates to the curable composition for forming a low refractive index film as described in any one of the first to fifth aspects, in which the hollow filler (A) includes hollow silica.

A seventh aspect of the present invention relates to a low refractive index film including a cured product of the curable composition for forming a low refractive index film as described in any one of the first to sixth aspects.

An eighth aspect of the present invention relates to an optical device including the low refractive index film as described in the seventh aspect.

A ninth aspect of the present invention relates to a method for producing a low refractive index film, the method including forming a coating film of the curable composition for forming a low refractive index film as described in any one of the first to sixth aspects; and
curing the coating film.

A tenth aspect of the present invention relates to the method for producing a low refractive index film as described in the ninth aspect, in which the coating film is formed by a spin coating method, a spray coating method, a slit coating method, a bar coating method, or a dip coating method.

An eleventh aspect of the present invention relates to the method for producing a low refractive index film as described in the ninth or tenth aspect, in which the coating film is cured by exposure to light.

The present invention can provide a curable composition for forming a low refractive index film of which a cured film having excellent heat resistance can be formed, a low refractive index film including a cured product of the curable composition, an optical device including the low refractive index film, and a method for producing a low refractive index film using the curable composition.

### DETAILED DESCRIPTION OF THE INVENTION

Hereinafter, embodiments of the present invention are described in detail, but the present invention is not limited to the following embodiments, and appropriate modification can be added in the scope of an object of the present invention.

Note here that “ . . . - . . . ” or “ . . . to . . . ” in this specification represents “ . . . (lower limit value) or more and . . . (upper limit value) or less” unless otherwise notified.

In this specification, the term merely referred to as “curable composition” means “curable composition for forming a low refractive index film” unless otherwise explained.

In this specification, “(meth)acrylate” includes both acrylate and methacrylate.

In this specification, “(meth)acrylic” includes both acrylic and methacrylic.

In this specification, “(meth)acryloyl” includes both acryloyl and methacryloyl.

### <<Curable Composition for Forming a Low Refractive Index Film>>

A curable composition for forming a low refractive index film contains a hollow filler (A), a polymerizable compound (B), and a polymerization initiator (C), and does not contain an alkali-soluble resin. The polymerizable compound (B) includes a compound (B1) having 5 or more polymerizable functional groups, and a compound (B2) having 1 or more and 3 or less polymerizable functional groups. A ratio (B1/B2) of a mass of the compound (B1) to a mass of the compound (B2) is 0.25 or more and 3 or less. When such a curable composition is used, a cured film having excellent heat resistance can be formed.

### <Hollow Filler (A)>

A curable composition includes a hollow filler (A) for forming a low refractive index film showing a refractive index to a desired degree. The hollow filler (A) is appropriately selected from hollow fillers incorporated in curable compositions conventionally used for the formation of low refractive index films, so as not to interfere with the object of the present invention.

The hollow filler (A) may be one kind of particle, or may be two or more kinds of particles in combination.

A hollow filler refers to a particle having, inside thereof, a cavity surrounded by an outer shell.

The percentage of voids of the hollow filler is preferably 10 to 80%, more preferably 40 to 80%, and particularly preferably 50 to 70% from the viewpoint that durability of the hollow filler (A) is good and that a low refractive index film with a low refractive index is formed easily.

An average particle diameter of the hollow filler (A) is not particularly limited as long as the object of the present invention is not inhibited. The average particle diameter of the hollow filler (A) is preferably 1 to 200 nm, more preferably 10 to 100 nm, and further preferably 40 to 80 nm.

The average particle diameter of the hollow filler (A) can be obtained from an image obtained by observing the dispersed hollow filler particles under a transmission electron microscope. Specifically, the following procedures 1) to 3) are carried out.
1) A projected area is obtained for each of a plurality of hollow filler particles.
2) The circular equivalent diameter of each hollow filler particle is obtained from the obtained projected area.
3) The number average value of the circular equivalent diameter of a plurality of hollow filler particles is calculated as the average particle diameter of the hollow filler (A).

Note here that the measurement of the average particle diameter is typically carried out on 300 or more hollow filler particles.

The specific surface area of the hollow filler (A) is preferably 10 to 2000 m²/g, more preferably 20 to 1800 m²/g, and particularly preferably 50 to 1500 m²/g.

The refractive index of the hollow filler (A) is preferably 1.10 to 1.40, more preferably 1.15 to 1.35, and particularly preferably 1.15 to 1.30. The refractive index herein is a refractive index for whole particles, and is not the refractive index of only outer shell constituting the hollow filler particles.

Materials of the hollow filler particle is preferably inorganic filler from the viewpoint of reduction of the refractive index of the low refractive index film. Examples of such inorganic materials include magnesium fluoride and silica particles. The inorganic material may be a crystalline material or an amorphous material.

Hollow silica particles are preferable as the hollow filler particles made of an inorganic filler because they are easy to form a low refractive index film having a low refractive index, easy to disperse stably in a curable composition, and inexpensive.

The average primary particle diameter of the inorganic hollow filler particles is preferably 1 to 100 nm, and more preferably 1 to 60 nm.

The inorganic hollow filler particles may be monodisperse particles or may include aggregates in which primary particles aggregate.

When the hollow filler (A) is an inorganic particle, the surface of the inorganic particle may be subjected to a physical surface treatment such as a plasma discharge treatment or a corona discharge treatment, or a chemical surface treatment with a surfactant, a coupling agent, or the like, for the purpose of improving the dispersion stability of the hollow filler (A) in a dispersion of the hollow filler (A) or in a curable composition, or for the purpose of enhancing the affinity and bonding property with a component such as the polymerizable compound (B).

Among such surface treatments, a chemical surface treatment using a coupling agent is preferable.

The coupling agent is preferably a titanium coupling agent, a silane coupling agent, or the like, and more preferably a silane coupling agent.

For example, when silica particles are treated with a silane coupling agent, an organosilyl group is bonded to the surface of the silica particles by the reaction between the silane coupling agent and the silanol groups on the surface of the silica particles.

Examples of the organic group introduced by the treatment of the silane coupling agent include a hydrocarbon group having 1 to 18 carbon atoms which may have an unsaturated bond, a halogenated hydrocarbon group having 1 to 18 carbon atoms which may have an unsaturated bond, and the like.

The surface treatment with a coupling agent may be carried out before the inorganic particles of the hollow filler (A) are blended in the curable composition. The surface treatment of the hollow filler (A) may be carried out by adding a coupling agent to the curable composition.

The hollow filler (A), such as inorganic particle, is preferably dispersed in a medium before preparing the curable composition because agglomeration is prevented and dispersion in the curable composition is easy.

When silica particles are used as the hollow filler (A), commercially available silica particles can be suitably used.

Specific examples of commercially available silica particles include, for example, THRULYA series (Isopropanol (IPA) dispersion, 4-methyl-2-pentanone (MIBK) dispersion, propylene glycol monomethyl ether dispersion, and the like) manufactured by JGC Catalysts and Chemicals Ltd.; Sirinax manufactured by Nittetsu Mining Co., Ltd.

As described above, the hollow filler (A) is preferably blended in a curable composition as a dispersion in a medium.

When the silica particles are blended in the curable composition as a dispersion, the content of the silica particles in the dispersion is preferably 10 to 50% by mass, more preferably 15 to 40% by mass, and particularly preferably 15 to 30% by mass.

When the hollow filler (A) is dispersed in a medium or a curable composition, a dispersant may be used.

Specific examples of the dispersant include dispersing resins such as polyamidoamine, salts of polyamidoamine, polycarboxylic acids, polycarboxylates, high molecular weight unsaturated acid esters, modified polyurethanes, modified polyesters, modified poly(meth)acrylates, (meth)acrylic copolymers, and naphthalenesulfonic acid formalin condensates.

Compounds such as polyoxyethylene alkylphosphate ester, polyoxyethylene alkylamine, and alkanolamine can be used as the dispersant.

Among the above dispersants, dispersing resins are preferable. Dispersed resins can be classified into linear polymers, terminal-modified polymers, graft-type polymers, and block-type polymers according to their structures.

The dispersed resin is adsorbed on the surface of the hollow filler particles and acts to prevent the agglomeration of the hollow filler particles. Therefore, a terminal-modified polymer, a graft-type polymer, or a block-type polymer having an anchor site to the surface of the hollow filler particle can be a preferable structure.

The mass average molecular weight (polystyrene equivalent value measured by the GPC method) of the dispersed resin is preferably 1000 to 200000, more preferably 2000 to 100000, and particularly preferably 5000 to 50000.

The dispersed resin is commercially available.

Specific examples of commercially available dispersion resins include:
Disperbyk-101 (polyamidoamine phosphate), Disperbyk-107 (carboxylic acid ester), Disperbyk-110 (copolymer including acid), Disperbyk-111 (polyamide), Disperbyk-130 (polyamide), Disperbyk-161 (high molecular copolymer), Disperbyk-162 (high molecular copolymer), Disperbyk-163 (high molecular copolymer), Disperbyk-164 (high molecular copolymer), Disperbyk-165 (high molecular copolymer), Disperbyk-166 (high molecular copolymer), Disperbyk-170 (high molecular copolymer), BYK—P104 (high molecular weight unsaturated polycarboxylic acid), and BYK—P105 (high molecular weight unsaturated polycarboxylic acid) manufactured by BYKChemie;
EFKA4047 (polyurethane), EFKA4050-4010-4165 (polyurethane), EFKA4330-4340 (block copolymer), EFKA4400-4402 (modified polyacrylate), EFKA5010 (polyester amide), EFKA5765 (high molecular weight polycarboxylate), EFKA6220 (fatty acid polyester), EFKA6745 (phthalocyanine derivative), and EFKA6750 (azo pigment derivative) manufactured by EFKA;
Azisper PB821, and Azisper PB822 manufactured by Ajinomoto Phantechno;
Florene TG-710 (Urethane Oligomer), Polyflow No. 50E (Acrylic Copolymer), and Polyflow No. 300 (Acrylic Copolymer) manufactured by Kyoeisha Chemical Co., Ltd.;
Disparon KS-860 (high molecular polyester amine salt), Disparon KS-873SN (high molecular polyester amine salt), Disparon KS-874 (high molecular polyester amine salt), Disparon 2150 (aliphatic polycarboxylic acid), Disparon 7004 (polyether ester), Disparon DA-703-50, Disparon DA-705, and Disparon DA-725 manufactured by Kusumoto Kasei;
Demol RN (naphthalene sulfonic acid formalin polycondensate), Demol N (naphthalene sulfonic acid formalin polycondensate), Demol MS (aromatic sulfonic acid formalin polycondensate), Demol C (aromatic sulfonic acid formalin polycondensate), Demol SN—B (aromatic sulfonic acid formalin polycondensate), Homogenol L-18 (high molecular polycarboxylic acid), Emulgen 920 (polyoxyethylene nonyl phenyl ether), Emulgen 930 (polyoxyethylene nonyl phenyl ether), Emulgen 935 (polyoxyethylene nonyl phenyl ether), Emulgen 985 (polyoxyethylene nonyl phenyl ether), and Acetamine 86 (stearylamine acetate), manufacture by Kao Corporation;
Solsparce 5000 (phthalocyanine derivative), Solsparce 22000 (azo pigment derivative), Solsparce 13240 (polyester amine), Solsparce 3000 (end-modified polymer), Solsparce 17000 (end-modified polymer), Solsparce 27000 (end-modified polymer), Solsparce 24000 (graft polymer), Solsparce 28000 (graft polymer), Solsparce 32000 (graft polymer), and Solsparce 38500 (graft polymer) manufactured by Lubrizol;
Nikkor T106 (polyoxyethylene sorbitan monooleate) and MYS-IEX (polyoxyethylene monostearate) manufactured by Nikko Chemical;
EFKA-46, EFKA-47, EFKA-47EA, EFKA Polymer 100, EFKA Polymer 400, EFKA Polymer 401, and EFKA Polymer 450 manufactured by Morishita Sangyo; and
Disperse Aid 6, Disperse Aid 8, Disperse Aid 15, and Disperse Aid 9100 manufactured by Sannopco.

Furthermore, as the dispersant, a nonionic, anionic or cationic surfactant can be used. These surfactants are commercially available.

Specific examples of commercially available surfactants include:
EFKA-745 manufactured by EFKA;
Organosiloxane polymer KP341 manufactured by Shin-Etsu Chemical;
Polymer Polyflow No. 75, Polymer Polyflow No. 90, and Polymer Polyflow No. 95 manufactured by Kyoeisha Oil & Fat Chemical Industry Co., Ltd.;
W001, W004, W005, and W017 manufactured by Yusho;
Solsparce 3000, Solsparce 5000, Solsparce 9000, Solsparce 12000, Solsparce 13240, Solsparce 13940, Solsparce 17000, Solsparce 24000, Solsparce 26000, Solsparce 28000 manufactured by Lubrizol Japan Ltd.;
Adekapulronic manufactured by ADEKA CORPORATION (registered trademark, and the same is true hereinafter) L31, Adekapulronic F38, Adekapulronic L42, Adekapulronic L44, Adekapulronic L61, Adekapulronic L64, Adekapulronic F68, Adekapulronic L72, Adekapulronic P95, Adekapulronic F77, Adekapulronic P84, Adekapulronic F87, Adekapulronic P94, Adekapulronic L101, Adekapulronic P103, Adekapulronic F108, Adekapulronic L121, and Adekapulronic P-123;
Isonet S-20 manufactured by Sanyo Chemical Industries, Ltd.;
Hinoact T-8000E manufactured by Kawaken Fine Chemical Co., Ltd.;
ELEBASE BA-100, ELEBASE BA-200, ELEBASE BCP-2, ELEBASE BUB-3, ELEBASE BUB-4, ELEBASE CP-800K, ELEBASE EDP-475, ELEBASE HEB-5, Fine Surf 270, Fine Surf 7045, Fine Surf 7085, Braunon DSP-12.5, Braunon DT-03, Braunon L-205, Braunon LPE-1007, Braunon O-205, Braunon S-202, Braunon S-204, Braunon S-207, Braunon S-205T manufactured by Aoki Oil & Fat Industries, Ltd.;
Emulgen A-500, Emulgen PP-290, Amito 102, Amito 105, Amito 302, Amito 320, Aminone PK-02S, Emanone CH-25, Emulgen 104P, Emulgen 108, Emulgen 404, Emulgen 408, Emulgen A-60, Emulgen A-90, Emulgen B-66, Emulgen LS-106, Emulgen LS-114, Leodol 430 V, Leodol 440 V, Leodol 460 V, Leodol TW-S106, Leodol TW-S120 V, Leodol Super TW-L120, Phosphanol ML-200, Emar 20 T, Emar E-27, Neoperex GS, Pelex NBL, Pelex SS—H, Pelex SS-L, Poise 532 A, Latemul ASK, Latemul E-118B, Latemul E-150 manufactured by Kao Corporation;
Newcargen 3000S, Newcargen FS-3PG, Newcargen FE-7PG, Pionine D-6414, Pionine A-24-EA, Pionine A-28-B, Pionine A-29-M, Pionine A-44-B, Pionine A-44TW manufactured by Takemoto Oil & Fat Co., Ltd.;
Dynol 604, Orphin PD-002W, Surfinol 2502, Surfinol 440, Surfinol 465, Surfinol 485, Surfinol 61 manufactured by Nisshin Chemical Industry Co., Ltd.;
EMULSOGEN COL-020, EMULSOGEN 070, and EMULSOGEN 080, manufactured by Clariant K.K.;
Pryserf A208B, Pryserf A210B, Pryserf A210G, Pryserf A219B, Pryserf AL, and Rabelin FC-45 manufactured by Daiichi Kogyo Seiyaku; and
AKYPO RLM100NV, AKYPO RLM45, AKYPO RLM45NV, AKYPO ECT-3, AKYPO ECT-3NEX, AKYPO ECT-7, Phosten HLP, Phosten HLP-1, and Phosten HLP-TEA manufactured by Nippon Surfactant Industries Co., Ltd.

These dispersants may be used alone or in combination of two or more.

The content of the dispersant in the curable composition is preferably 1 to 100% by mass, more preferably 5 to 80% by mass, and particularly preferably 10 to 60% by mass with respect to the mass of the hollow filler. When the dispersant is a dispersed resin, the use amount of the dispersant is preferably 5 to 100% by mass, and more preferably 10 to 80% by mass with respect to the mass of the hollow filler.

The use amount of the hollow filler (A) in the curable resin composition is not particularly limited as long as the object of the present invention is not inhibited. The content of the hollow filler (A) in the curable composition is preferably 80% by mass or less, preferably 20 to 80% by mass, and particularly preferably 30 to 70% by mass with respect to the mass of the curable composition excluding the mass of the organic solvent (S) to be described later.

### <Polymerizable Compound (B)>

A curable resin composition contains a polymerizable compound (B). A polymerizable compound (B) includes a compound (B1) having 5 or more polymerizable functional groups and a compound (B2) having 1 or more and 3 or less polymerizable functional groups. A ratio (B1/B2) of a mass of the compound (B1) to the mass of the compound (B2) is 0.25 or more and 3 or less.

Examples of the polymerizable functional group include ethylenically unsaturated groups. Examples of the ethylenically unsaturated group include a (meth)acryloyl group.

### (Compound (B1) Having 5 or More Polymerizable Functional Groups)

The number of polymerizable functional groups of the compound (B1) is 5 or more, preferably 5 to 10, and more preferably 5 or 6.

Two types or more of the compounds (B1) may be used in combination.

As the compound (B1), a compound represented by the following formula (b1) is preferable.

(MA-(O—R¹¹—(CO)ₙ₁₃)ₙ₁₂—X)ₙ₁₁-A-((X)ₙ₁₅—R¹²)ₙ₁₄ (b1)

(in the formula (b1), A is a hexavalent organic group, MA each independently is a (meth)acryloyl group, X each independently is an oxygen atom, —NH—, or —N(CH₃)—; R¹¹ each independently is an alkylene group having 1 to 10 carbon atoms; R¹² is a hydrogen atom, an alkyl group having 1 to 4 carbon atoms, or an acyl group having 1 to 4 carbon atoms; n11 is 5 or 6; n12 is each independently an integer from 0 to 10; n13 is each independently 0 or 1; n14 is 0 or 1; n15 is 0 or 1; and n11+n14 is 6.

The number of carbon atoms of the hexavalent organic group represented by A is preferably 2 or more and 20 or less, more preferably 6 or more and 15 or less, and further preferably 10 or more and 12 or less.

Examples of the hexavalent organic group represented by A include an aliphatic hydrocarbon group; an aromatic hydrocarbon group; a heterocyclic group; a group in which two or more groups selected from the group consisting of aliphatic hydrocarbon groups, aromatic hydrocarbon groups, and heterocyclic groups are bonded through a single bond or a divalent linking group; and the like. Among them, an aliphatic hydrocarbon group and a group in which two or more aliphatic hydrocarbon groups are bonded through a divalent linking group are preferable, and a group in which two or more aliphatic hydrocarbon groups are bonded through a divalent linking group is more preferable.

Examples of the aliphatic hydrocarbon group include a linear or branched aliphatic hydrocarbon group, an aliphatic hydrocarbon group containing a ring in its structure, and the like. Among them, linear or branched aliphatic hydrocarbon groups are preferable, and linear or branched saturated aliphatic hydrocarbon groups are more preferable.

Examples of divalent linking groups include —CONH—, —NH—, —N═N—, —CH═N—, —COO—, —O—, —CO—, —SO—, —SO₂—, —S—, —S—S—, and the like. Among them, —O— is preferable.

As the hexavalent organic group represented by A includes, for example, a group having the following structure.

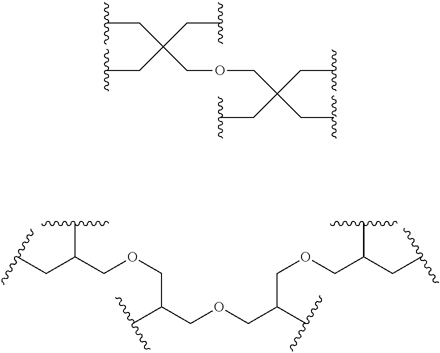 [SMILES: *CC(C*)(C*)COCC(C*)(C*)C* ; *CC(*)COCC(*)COCC(*)COCC(*)C*]

X is preferably an oxygen atom.

The number of carbon atoms of the alkylene group represented by R¹¹ is preferably 1 or more and 5 or less, and more preferably 2 or 3.

Examples of the alkylene group, represented by R¹¹, having 1 to 10 carbon atoms include an ethane-1,2-diyl group, a propane-1,2-diyl group, a propane-1,3-diyl group, a butane-1,4-diyl group, and a propane-1,5-diyl group. Among them, the ethane-1,2-diyl group, propane-1,2-diyl group and propane-1,3-diyl group are preferable.

Examples of the alkyl group, represented by R¹², having 1 to 4 carbon atoms include a methyl group, an ethyl group, an n-propyl group, an isopropyl group, an n-butyl group, an isobutyl group, a sec-butyl group, and a tert-butyl groups. Among these alkyl groups, a methyl group and an ethyl group are preferable.

The number of carbon atoms of the acyl group represented by R¹² is preferably 1 or more and 3 or less.

Examples of the acyl group, represented by R¹², having 1 to 4 carbon atoms include a group represented by —COR (R is a linear or branched alkyl group).

As R¹², a hydrogen atom and an acyl group having 1 to 4 carbon atoms are preferable.

n12 is preferably 0 or more and 5 or less, more preferably 0 or more and 3 or less, and further preferably 0.

n13 is preferably 0.

n15 is preferably 1.

Preferable examples of the compound represented by formula (b1) include dipentaerythritol penta(meth)acrylate, dipentaerythritol hexa(meth)acrylate, alkylene oxide-modified dipentaerythritol penta(meth)acrylate, alkylene oxide-modified dipentaerythritol hexa(meth)acrylate, caprolactone-modified dipentaerythritol penta(meth)acrylate, caprolactone-modified dipentaerythritol hexa(meth)acrylate, KAYARAD D-310 manufactured by Nippon Kayaku Co., Ltd., SA-TE manufactured by Sakamoto Pharmaceutical Industry Co., Ltd., and the like. Among them, dipentaerythritol penta(meth)acrylate and dipentaerythritol hexa(meth)acrylate are more preferable.

### (Compound (B2) Having 1 or More and 3 or Less Polymerizable Functional Groups)

The number of polymerizable functional groups in the compound (B2) is 1 or more and 3 or less, and preferably 3.

Two kinds of the compounds (B2) may be used in combination.

Examples of the compound (B2) having one polymerizable functional group include (meth)acrylamide, methylol (meth)acrylamide, methoxymethyl (meth)acrylamide, ethoxymethyl (meth)acrylamide, propoxymethyl (meth)acrylamide, butoxymethoxymethyl (meth)acrylamide, N-methylol (meth)acrylamide, N-hydroxymethyl (meth)acrylamide, (meth)acrylic acid, fumaric acid, maleic acid, maleic anhydride, itaconic acid, itaconic anhydride, citraconic acid, citraconic anhydride, crotonic acid, 2-acrylamide-2-methylpropanesulfonic acid, tert-butylacrylamide sulfonic acid, methyl (meth)acrylate, ethyl (meth)acrylate, butyl (meth)acrylate, 2-ethylhexyl (meth)acrylate, cyclohexyl (meth)acrylate, 2-hydroxyethyl (meth)acrylate, 2-hydroxypropyl (meth)acrylate, 2-hydroxybutyl (meth)acrylate, 2-phenoxy-2-hydroxypropyl (meth)acrylate, 2-(meth)acryloyloxy-2-hydroxypropyl phthalate, glycerol mono (meth)acrylate, tetrahydrofurfuryl (meth)acrylate, dimethylaminoethyl (meth)acrylate, glycidyl (meth)acrylate, 2,2,2-trifluoroethyl (meth)acrylate, 2,2,3,3-tetrafluoropropyl (meth)acrylate, half (meth)acrylate of phthalic acid derivatives, isobornyl (meth)acrylate, and the like.

Examples of the compound (B2) having two or three polymerizable functional groups include ethylene glycol di (meth)acrylate, diethylene glycol di(meth)acrylate, tetraethylene glycol di(meth)acrylate, propylene glycol di(meth)acrylate, polypropylene glycol di(meth)acrylate, butylene glycol di(meth)acrylate, neopentyl glycol di(meth)acrylate, 1,6-hexane glycol di(meth)acrylate, trimethylolpropane tri(meth)acrylate, alkylene oxide-modified trimethylolpropane tri(meth)acrylate, glycerol di(meth)acrylate, pentaerythritol di(meth)acrylate, pentaerythritol tri(meth)acrylate, 2,2-bis(4-(meth)acryloxydiethoxyphenyl)propane, 2,2-bis(4-(meth)acryloxypolyethoxyphenyl)propane, 2-hydroxy-3-(meth)acryloyloxypropyl (meth)acrylate, ethylene glycol diglycidyl ether di(meth)acrylate, diethylene glycol diglycidyl ether di(meth)acrylate, phthalic acid diglycidyl ester di(meth)acrylate, glycerol tri(meth)acrylate, tri(meth)acrylic formal, tricyclodecanedimethanol di(meth)acrylate, and the like.

As the compound (B2), compounds represented by the following formula (b2-1) or (b2-2) are preferable.

(MA-(O—R²¹—(CO)ₙ₂₂)ₙ₂₁—X—CH₂)₃—C—CH₂—R²² (b2-1)

(MA-(O—R²¹—(CO)ₙ₂₂)ₙ₂₁—X—CH₂)₂—CH—X—((CO)ₙ₂₂—R²¹—O)ₙ₂₁-MA (b2-2)

(in the formula (b2-1) and the formula (b2-2), MA each independently is a (meth)acryloyl group, X each independently is an oxygen atom, —NH—, or —N(CH₃)—, R²¹ each independently is an alkylene group having 1 or more and 10 or less carbon atoms, R²² is a hydroxyl group or an alkyl group having 1 to 4 carbon atoms, n21 each independently an integer of 0 or more and 10 or less, n22 each independently is 0 or 1).

X is preferably an oxygen atom.

The number of carbon atoms of the alkylene group represented by R²¹ is preferably 1 or more and 5 or less, and more preferably 2 or 3.

Examples of the alkylene group, represented by R²¹, having 1 to 10 carbon atoms include an ethane-1,2-diyl group, a propane-1,2-diyl group, a propane-1,3-diyl group, a butane-1,4-diyl group, and a propane-1,5-diyl group. Among them, an ethane-1,2-diyl group, a propane-1,2-diyl group, and a propane-1,3-diyl group are preferable.

Examples of the alkyl groups, represented by R²², having 1 to 4 carbon atoms include a methyl group, an ethyl group, an n-propyl group, an isopropyl group, an n-butyl group, an isobutyl group, a sec-butyl group, and a tert-butyl group.

Among these alkyl groups, a methyl group and an ethyl group are preferable.

n21 is preferably 0 or more and 5 or less, and more preferably 1 or more and 3 or less.

n22 is preferably 0.

Preferable examples of the compound represented by formula (b2-1) or (b2-2) include trimethylolpropane tri(meth)acrylate, alkylene oxide-modified trimethylolpropane tri(meth)acrylate, caprolactone-modified trimethylolpropane tri(meth)acrylate, glycerol tri(meth)acrylate, alkylene oxide-modified glycerol tri(meth)acrylate, caprolactone-modified glycerol tri(meth)acrylate, and the like. Among them, alkylene oxide-modified trimethylolpropane tri(meth)acrylate is more preferable.

A ratio (B1/B2) of a mass of the compound (B1) to a mass of the compound (B2) is 0.25 or more and 3 or less, preferably 1.1 or more and 2.5 or less, and more preferably 1.25 or more and 2 or less. When the above ratio is 0.25 or more and 3 or less, a cured film having excellent heat resistance can be formed.

The total content of the compound (B1) and the compound (B2) in the polymerizable compound (B) is preferably 80% by mass or more, more preferably 90% by mass or more, further preferably 95% by mass or more, and may be 100% by mass.

The content of the polymerizable compound (B) is preferably 20 to 80% by mass, more preferably 30 to 70% by mass with respect to the mass of the curable composition excluding the mass of the organic solvent (S) to be described later.

### <Polymerization Initiator (C)>

The curable composition contains a polymerization initiator (C).

The polymerization initiator (C) is not particularly limited, and conventionally known photopolymerization initiators, thermal polymerization initiators, and the like, can be used. Among them, a photopolymerization initiator is preferable. The polymerization initiator may be used alone or in combination of two or more kinds.

The photopolymerization initiator is not particularly limited, and conventionally known photopolymerization initiators can be used.

Specific examples of the photopolymerization initiators include 1-hydroxycyclohexylphenyl ketone, 2-hydroxy-2-methyl-1-phenylpropane-1-one, 1-[4-(2-hydroxyethoxy)phenyl]-2-hydroxy-2-methyl-1-propane-1-one, 1-(4-isopropylphenyl)-2-hydroxy-2-methylpropane-1-one, 1-(4-dodecylphenyl)-2-hydroxy-2-methylpropane-1-one, 2,2-dimethoxy-1,2-diphenylethane-1-one, bis(4-dimethylaminophenyl)ketone, 2-methyl-1-[4-(methylthio)phenyl]-2-morpholinopropane-1-one, 2-benzyl-2-dimethylamino-1-(4-morpholinophenyl)-butane-1-one, O-acetyl-1-[6-(2-methylbenzoyl)-9-ethyl-9H-carbazole-3-yl]ethanone oxime, O-acetyl-1-[6-(pyrrole-1-ylcarbonyl)-9-ethyl-9H-carbazole-3-yl]ethanone oxime, (9-ethyl-6-nitro-9H-carbazole-3-yl)[4-(2-methoxy-1-methylethoxy)-2-methylphenyl]methanone O-acetyl oxime, 2-(benzoyloxyimino)-1-[4-(phenylthio)phenyl]-1-octanone, 2,4,6-trimethylbenzoyldiphenylphosphine oxide, 4-benzoyl-4′-methyldimethyl sulfide, 4-dimethylaminobenzoic acid, methyl 4-dimethylaminobenzoate, ethyl 4-dimethylaminobenzoate, butyl 4-dimethylaminobenzoate, 4-dimethylamino-2-ethylhexylbenzoic acid, 4-dimethylamino-2-isoamylbenzoic acid, benzyl-β-methoxyethylacetal, benzyldimethylketal, 1-phenyl-1,2-propanedione-2-(O-ethoxycarbonyl)oxime, methyl o-benzoylbenzoate, 2,4-diethylthioxanthone, 2-chlorothioxanthone, 2,4-dimethylthioxanthone, 1-chloro-4-propoxythioxanthone, thioxanthene, 2-chlorothioxanthene, 2,4-diethylthioxanthene, 2-methylthioxanthene, 2-isopropylthioxanthene, 2-ethylanthraquinone, octamethylanthraquinone, 1,2-benzanthraquinone, 2,3-diphenylanthraquinone, azobisisobutyronitrile, benzoyl peroxide, cumene hydroperoxide, 2-mercaptobenzimidazole, 2-mercaptobenzoxazole, 2-mercaptobenzothiazole, 2-(o-chlorophenyl)-4,5-di(m-methoxyphenyl)-imidazolyl dimer, benzophenone, 2-chlorobenzophenone, p,p′-bisdimethylaminobenzophenone, 4,4′-bisdiethylaminobenzophenone, 4,4′-dichlorobenzophenone, 3,3-dimethyl-4-methoxybenzophenone, benzyl, benzoin, benzoin methyl ether, benzoin ethyl ether, benzoin isopropyl ether, benzoin-n-butyl ether, benzoin isobutyl ether, benzoin butyl ether, acetophenone, 2,2-diethoxyacetophenone, p-dimethylacetophenone, p-dimethylaminopropiophenone, dichloroacetophenone, trichloroacetophenone, p-tert-butylacetophenone, p-dimethylaminoacetophenone, p-tert-butyltrichloroacetophenone, p-tert-butyldichloroacetophenone, α,α-dichloro-4-phenoxyacetophenone, thioxanthone, 2-methylthioxanthone, 2-isopropylthioxanthone, dibenzosuberone, pentyl-4-dimethylaminobenzoate, 9-phenylacridine, 1,7-bis-(9-acridinyl)heptane, 1,5-bis-(9-acridinyl)pentane, 1,3-bis-(9-acridinyl)propane, p-methoxytriazine, 2,4,6-tris(trichloromethyl)-s-triazine, 2-methyl-4,6-bis(trichloromethyl)-s-triazine, 2-[2-(5-methylfuran-2-yl)ethenyl]-4,6-bis-(trichloromethyl)-s-triazine, 2-[2-(furan-2-yl)ethenyl]-4,6-bis(trichloromethyl)-s-triazine, 2-[2-(4-diethylamino-2-methylphenyl)ethenyl]-4,6-bis(trichloromethyl)-s-triazine, 2-[2-(3,4-dimethoxyphenyl)ethenyl]-4,6-bis(trichloromethyl)-s-triazine, 2-(4-methoxyphenyl)-4,6-bis(trichloromethyl)-s-triazine, 2-(4-ethoxystyryl)-4,6-bis(trichloromethyl)-s-triazine, 2-(4-n-butoxyphenyl)-4,6-bis(trichloromethyl)-s-triazine, 2,4-bis-trichloromethyl-6-(3-bromo-4-methoxy)phenyl-s-triazine, 2,4-bis-trichloromethyl-6-(2-bromo-4-methoxy)phenyl-s-triazine, 2,4-bis-trichloromethyl-6-(3-bromo-4-methoxy)styrylphenyl-s-triazine, 2,4-bis-trichloromethyl-6-(2-bromo-4-methoxy)styrylphenyl-s-triazine, and the like. These photopolymerization initiators can be used alone or in combination of two or more kinds.

The thermal polymerization initiator is not particularly limited, and conventionally known thermal polymerization initiators can be used.

Specific examples of the thermal polymerization initiator include organic peroxides such as ketone peroxide (methylethylketone peroxide, cyclohexanone peroxide, and the like), peroxyketals (2,2-bis(tert-butylperoxide)butane, 1,1-bis-(tert-butylperoxide)cyclohexane, and the like), hydroperoxides (tert-butylhydroperoxide, cumene hydroperoxide, and the like), dialkyl peroxides (di-tert-butylperoxide (Perbutyl® D (manufactured by Nippon Oil Corporation), and di-tert-hexyl peroxide (Perhexyl® D (manufactured by Nippon Oil Corporation)), and the like), diacylperoxide (Isobutyryl peroxide, lauroyl peroxide, benzoyl peroxide, and the like), peroxydicarbonate (diisopropylperoxydicarbonate, and the like), peroxyesters (tert-butylperoxyisobutyrate, 2,5-dimethyl-2,5-di(benzoylperoxy)hexane, and the like), and azo compounds such 1,1′-azobis(cyclohexane-1-carbonitrile), 2,2′-azobisisobutyronitrile, 2,2′-azobis(2,4-dimethyl-4-methoxyvaleronitrile), 2,2′-azobis(2-methylpropionamidine)dihydrochloride, 2,2′-azobis[2-methyl-N-(2-propenyl) propionamidine]dihydrochloride, 2,2′-azobis(2-methylpropionamide), 2,2′-azobis[2-methyl-N-(2-hydroxyethyl)propionamide], 2,2′-azobis(2-methylpropane), 2,2′-azobis(2,4,4-trimethylpentane), dimethyl-2,2′-azobis(2-methylpropionate), and the like. These thermal polymerization initiators can be used alone or in combination of two or more kinds.

The content of the polymerization initiator (C) is preferably 0.5 to 30% by mass, more preferably 1 to 20% by mass with respect to the mass of the curable composition excluding the mass of the organic solvent (S) to be described later. When the content of the polymerization initiator (C) is within the above range, a curable composition having good curability can be obtained.

### <Surfactant (D)>

The curable composition preferably contains a surfactant (D).

As the surfactant (D), any of a nonionic surfactant, a cationic surfactant, an anionic surfactant, and an amphoteric surfactant can be used. The surfactant (D) may be a fluorine-based surfactant, a silicon-based surfactant, or the like. The surfactant (D) is preferably a fluorine-based surfactant or a silicon-based surfactant, and more preferably a silicon-based surfactant. Two or more surfactants (D) may be used in combination.

The fluorine-based surfactant is not particularly limited as long as the surfactant contains a fluorine atom, and may be any one of an anionic surfactant, a cationic surfactant, or a nonionic surfactant.

Two or more kinds of fluorine-based surfactants may be used in combination.

Specific examples of fluorinated surfactants include, but are not limited to, commercially available fluorinated surfactants such as BM-1000, BM-1100 (all manufactured by BM Chemie), Megafac F142D, Megafac F172, Megafac F173, and Megafac F183 (all manufactured by Dainippon Ink & Chemicals), Florard FC-135, Florard FC-170C, Florard FC-430, and Florard FC-431 (all manufactured by Sumitomo 3M), Surfron S-112, Surfron S-113, Surfron S-131, Surfron S-141, and Surfron S-145 (all manufactured by Asahi Glass), and SH-28PA, SH-190, SH-193, SZ-6032, and SF-8428 (all manufactured by Toray Silicone).

Furthermore, as the fluorine-based surfactant, a compound having a fluoroalkyl group in a side chain is also preferable.

Examples of the compound having a fluoroalkyl group in the side chain include compounds represented by formulae (e-1) to (e-4) below.

In the formula (e-1) and formula (e-2), x1 is an integer of 0 to 7.

In the formula (e-3), x2 is an integer of 0 to 8.

In the formula (e-4), x3 is an integer of 6 to 20.

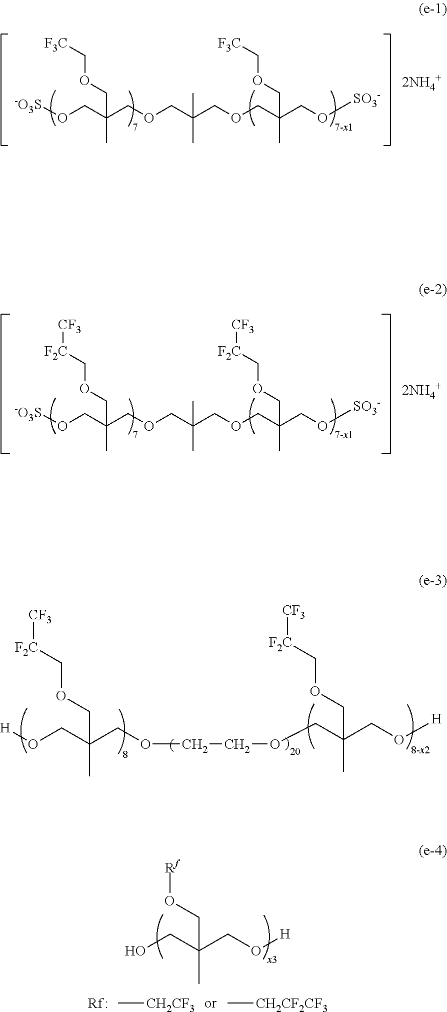

As the silicon-based surfactant, a polysiloxane-based surfactant is preferable.

The silicon-based surfactant is a surfactant containing silicon atoms. The polysiloxane-based surfactant is a surfactant having a main chain including repeated Si—O bonds.

Examples of the polysiloxane-based surfactant include polyether-modified polydimethylsiloxane, polyester-modified polydimethylsiloxane, aralkyl-modified polymethylalkylsiloxane, and the like.

Polysiloxane-based surfactants are commercially available, and examples thereof include BYK-331, BYK-310, and BYK-322 manufactured by Bic Chemie Japan Co., Ltd.; and TEGO Glide 440 manufactured by Evonik.

The content of the surfactant (D) is preferably 0.001 to 3% by mass, more preferably 0.001 to 2% by mass, still more preferably 0.001 to 1.5% by mass, and most preferably 0.001 to 1% by mass with respect to the sum of the mass of the hollow filler (A) and the mass of the polymerizable compound (B) in the curable composition.

### <Alkali-Soluble Resin>

The curable composition does not contain an alkali-soluble resin.

The alkali-soluble resin as used herein refers to a resin that dissolves in a film thickness of 0.01 μm or more when a resin film having a thickness of 1 μm is formed on a substrate with a resin solution having a resin concentration of 20% by mass (solvent: propylene glycol monomethyl ether acetate) and immersed in an aqueous solution of tetramethylammonium hydroxide (TMAH) having a concentration of 0.05% by mass for 1 minute.

Such alkali-soluble resins include alkali-soluble resins incorporated into various compositions used in processes including development with an alkali developing solution.

### <Organic Solvent (S)>

The curable composition preferably contains an organic solvent (S) for improving coating properties and adjusting viscosity.

Specific examples of the organic solvent (S) include an alkane monool such as methanol, ethanol, n-propanol, isopropanol, and n-butanol; (poly) alkylene glycol monoalkyl ethers such as ethylene glycol monomethyl ether, ethylene glycol monoethyl ether, ethylene glycol mono-n-propyl ether, ethylene glycol mono-n-butyl ether, diethylene glycol monomethyl ether, diethylene glycol monoethyl ether, diethylene glycol mono-n-propyl ether, diethylene glycol mono-n-butyl ether, triethylene glycol monomethyl ether, triethylene glycol monoethyl ether, propylene glycol monomethyl ether, propylene glycol monoethyl ether, propylene glycol mono-n-propyl ether, propylene glycol mono-n-butyl ether, 3-methoxy-n-butanol, dipropylene glycol monomethyl ether, dipropylene glycol monoethyl ether, dipropylene glycol mono-n-propyl ether, dipropylene glycol mono-n-butyl ether, tripropylene glycol monomethyl ether, and tripropylene glycol monoethyl ether; (poly) alkylene glycol monoalkyl ether acetates such as ethylene glycol monomethyl ether acetate, ethylene glycol monoethyl ether acetate, diethylene glycol monomethyl ether acetate, diethylene glycol monoethyl ether acetate, diethylene glycol monobutyl ether acetate, propylene glycol monomethyl ether acetate (PGMEA), propylene glycol monoethyl ether acetate; other ethers such as diethylene glycol dimethyl ether, diethylene glycol methyl ethyl ether, diethylene glycol diethyl ether, and tetrahydrofuran; ketones such as methyl ethyl ketone, cyclohexanone, 2-heptanone, and 3-heptanone; lactic acid alkyl esters such as methyl 2-hydroxypropionate and ethyl 2-hydroxypropionate; other esters such as ethyl 2-hydroxy-2-methylpropionate, methyl 3-methoxypropionate, ethyl 3-methoxypropionate, methyl 3-ethoxypropionate, ethyl 3-ethoxypropionate, ethoxyethyl acetate, hydroxyethyl acetate, methyl 2-hydroxy-3-methylbutanoic acid methyl, 3-methoxybutylacetate, 3-methyl-3-methoxybutyl acetate, 3-methyl-3-methoxybutyl propionate, ethyl acetate, n-propyl acetate, i-propyl acetate, n-butyl acetate, i-butyl acetate, n-pentyl formate, i-pentyl acetate, benzyl acetate, n-butyl propionate, ethyl butyrate, n-propyl butyrate, i-propyl butyrate, n-butyl butyrate, methyl pyruvate, ethyl pyruvate, n-propyl pyruvate, methyl acetoacetate, ethyl acetoacetate, ethyl 2-oxobutanoate, and 1,4-butanediol diacetate; aromatic hydrocarbons such as toluene and xylene; and nitrogen-containing polar organic solvents such as N-methyl-2-pyrrolidone, N,N-dimethylformamide, N,N-dimethylacetamide, N,N-dimethylisobutylamide, N,N-diethylacetamide, N,N-diethylformamide, N-methylcaprolactam, 1,3-dimethyl-2-imidazolidinone, pyridine, N,N,N′,N′-tetramethylurea, and the like.

Among them, 1,4-butanediol diacetate, (poly)alkylene glycol monoalkyl ether acetates, and (poly)alkylene glycol monoalkyl ethers are preferable, and (poly) alkylene glycol monoalkyl ethers are more preferable.

Furthermore, an organic solvent (S) including a nitrogen-containing polar organic solvent is preferable in view of solubility of each component and the like. Examples of the nitrogen-containing polar organic solvents include N,N,N′,N′-tetramethylurea or the like.

These solvents can be used alone or in combination of two or more kinds.

The content of the organic solvent (S) is not particularly limited, and is appropriately set depending on the coating film thickness at a concentration that can be applied to a substrate or the like. For example, the viscosity of the curable composition is preferably 1 to 500 cp, more preferably 1 to 50 cp, and still more preferably 1 to 30 cp. Furthermore, the solid content concentration of the curable composition is preferably 1 to 50% by mass, and more preferably 1 to 20% by mass.

### <Other Components>

The curable composition may optionally contain additives such as a photoacid generator, an adhesion improver, a thermal polymerization inhibitor, a defoaming agent, a colorant, a silane coupling agent, and the like. Any one of the additives can be conventionally known additives.

The curable composition preferably includes a silane coupling agent because it is easy to form a low refractive index film having a good shape and excellent adhesion to the substrate. As the silane coupling agent, conventionally known silane coupling agents can be used without any particular limitation.

### <<Method for Producing Low Refractive Index Film>>

As a method for producing a low refractive index film, a conventionally known method for producing a low refractive index film using a curable composition including a polymerizable compound (B) can be employed without particular limitation.

An example of suitable methods for producing a low refractive index film includes:
forming a coating film of the above-described curable composition; and
curing the coating film.

In order to form a low refractive index film using a curable composition, the curable composition is firstly coated on a substrate selected according to the use of the low refractive index film to form a coating film.

As the substrate, when an image sensor is formed, for example, a substrate having an RGB colored film on a semiconductor layer of silicon or the like and a microlens on the colored film is used.

The method of forming the coating film is not particularly limited, and may be carried out using, for example, a contact transfer type coating device such as a roll coater, a reverse coater, and a bar coater, or a non-contact type coating device such as a spinner (a spin coater and a rotary coater), a dip coater, a spray coater, a slit coater, and a curtain flow coater. Among them, a spin coating method using a spinner, a spray coating method using a spray coater, a slit coating method using a slit coater, a bar coating method using a bar coater, and a dip coating method using a dip coater are preferable.

The applied curable composition is dried if necessary to constitute a coating film. The drying method is not particularly limited, and includes, for example, (1) drying on a hot plate at a temperature of 80 to 120° C., and preferably 90 to 100° C. for 60 to 120 seconds, (2) leaving at room temperature for several hours to several days, and (3) placing in a warm air heater or infrared heater for several tens of minutes to several hours to remove the solvent.

Next, the coating film is cured. The curing method is not particularly limited, and may be exposure, heating, or a combination of exposure to light and heating. Among them, curing by exposure to light is preferable. The exposure is carried out by irradiating with active energy rays such as ultraviolet rays and excimer laser beams.

Next, the cured film may be subjected to baking (post-baking). The baking temperature is not particularly limited, but is preferably 180 to 250° C., and more preferably 220 to 230° C. The baking time is typically 10 to 90 minutes, and preferably 20 to 60 minutes.

The cured film thus formed can be suitably used as a low refractive index film. When the cured film is used as the low refractive index film, the refractive index (wavelength: 633 nm, measuring temperature: 25° C.) of the low refractive index film is preferably 1.4 or less, and more preferably 1.25 to 1.38.

The low refractive index film can be preferably used in an optical device such as an image sensor. In the image sensor, when the low refractive index film is applied as a coating layer for covering the microlens formed on the RGB colored film, the occurrence of flare in the image sensor is suppressed by improving the reflection of light incident on the microlens.

Since the curable composition can form a cured film excellent in heat resistance, it can be used for manufacturing an optical device requiring a heat treatment process such as solder reflow or post-baking.

### EXAMPLES

The present invention will be described in more detail based on Examples, but the present invention is not limited to these Examples.

### Examples 1 to 8, and Comparative Examples 1 to 6

Curable resin compositions of Examples and Comparative Examples were obtained by mixing the following hollow filler (A) in an amount described in Table 1, the polymerizable compound (B) in a type and amount described in Table 1, the polymerization initiator (C) in an amount described in Table 1, and 0.01 parts by mass of the following surfactant (D) in a type described in Table 1 with the following organic solvent (S) so that the solid content concentration became 31% by mass.

As the hollow filler (component (A)), THRULYA 4330 (product name, manufactured by JGC Catalysts and Chemicals Ltd., a dispersion solution of hollow silica particles having an average primary particle diameter of 60 nm and a solid content concentration of 30% by mass) was used.

As the polymerizable compound (component (B)), the following B1 to B4 were used.
B1: KAYARAD DPHA (product name, manufactured by Nippon Kayaku Co., Ltd., a mixture of dipentaerythritol hexaacrylate and dipentaerythritol pentaacrylate)
B2: M-360 (product name, manufactured by Toagose Co., Ltd., Trimethylolpropane EO-modified triacrylate represented by the following formula, n≈2)

[CH₂═CHCO—(OC₂H₄)ₙ—OCH₂]₃—CCH₂CH₃
B3: NK ester A-DCP (product name, manufactured by SHIN-NAKAMURA CHEMICAL Co., Ltd., tricyclodecanedimethanol diacrylate)
B4: Light ester IB-X (product name, manufactured by Kyoeisha Chemical Co., Ltd., isobornyl methacrylate)

As the polymerization initiator (component (C)), 1-1-hydroxycyclohexyl phenyl ketone was used.

As the surfactant (component (D)), the following D1 to D3 were used.
D1: PF-656 (product name, manufactured by Omnova, fluorine-based surfactant represented by the following formula)

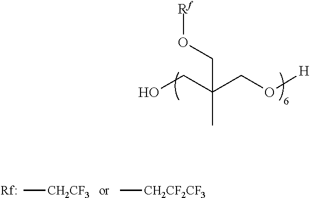

D2: BYK-310 (product name, manufactured by Bic Chemie Japan Co., Ltd., polyester-modified polydimethylsiloxane, silicon-based surfactant)
D3: TEGO Glide 440 (product name, manufactured by Evonik, polyether-modified polysiloxane copolymer, silicon-based surfactant)

As the organic solvent (component (S)), propylene glycol monomethyl ether was used.

### [Evaluation]

The appearance, refractive index, and heat resistance of the curable resin compositions of Examples and Comparative Examples were evaluated according to the following methods. The results of these evaluations are shown in Table 1.

### (Appearance)

The curable resin compositions of the respective Examples and the Comparative Examples were coated on a glass substrate with a coating film thickness of 3000 nm using a spin coater (MS-B 200 manufactured by Mikasa Co., Ltd.). The formed coating film was heated (pre-baked) at 100° C. for 1 minute, and then exposed at 1 J/cm² (in a vacuum atmosphere of 200 Pa) by an exposure device (imprint device ST-200 manufactured by Shibaura Kikai Co., Ltd.) to obtain a cured film. When the appearance of the obtained cured film was colorless and transparent, the appearance was evaluated as “A”, and when the appearance was cloudy, it was evaluated as “B”.

### (Refractive Index)

The curable resin compositions of Examples and Comparative Examples were coated on a silicon substrate using a spin coater (MS-B 200 manufactured by Mikasa Co., Ltd.) so that a coating film thickness was 1000 nm. The formed coating film was heated (pre-baked) at 100° C. for 1 minute, and then exposed at 1 J/cm² (in a vacuum atmosphere of 200 Pa) by an exposure device (imprint device ST-200 manufactured by Shibaura Kikai Co., Ltd.) to obtain a cured film. The refractive index of the obtained cured film was measured using a refractive index measuring device (M-2000 spectroscopic ellipsometer manufactured by J.A. Woollam).

### (Heat Resistance)

The film thickness of the cured film obtained in the appearance evaluation was measured. The operation of heating the cured film at 260° C. for 10 seconds was repeated 3 times, and the film thickness of the cured film after heating was measured. The change rate between the film thicknesses before and after heating was calculated based on the following equation, and a case where the film thickness change rate was 1% or less was evaluated as “A”, a case where the change rate was over 1% and 2% or less was evaluated as “B”, and a case where the change rate was over 2% was evaluated as “C”.

Film thickness change rate (%)=(|Film thickness before heating−film thickness after heating|/film thickness before heating)×100

TABLE 1

| | (A) | (B) | | (C) | | | | |
|---|---|---|---|---|---|---|---|---|
| | Component | Component | | Component | (D) | Evaluation | | |
| | Part by | | Part by | Part by | Component | | Refractive | Heat |
| | mass | Type | mass | mass | Type | Appearance | index | resistance |
| Example 1 | 60 | B1/B2 | 24/16 | 1 | D1 | A | 1.35 | A |
| Example 2 | 60 | B1/B2 | 16/24 | 1 | D1 | A | 1.35 | B |
| Example 3 | 60 | B1/B2 | 28/12 | 1 | D1 | A | 1.35 | B |
| Example 4 | 60 | B1/B2 | 8/32 | 1 | D1 | A | 1.35 | B |
| Example 5 | 60 | B1/B2 | 24/16 | 1 | D2 | A | 1.35 | A |
| Example 6 | 60 | B1/B2 | 24/16 | 1 | D3 | A | 1.35 | A |
| Example 7 | 60 | B1/B3 | 24/16 | 1 | D1 | A | 1.36 | B |
| Example 8 | 60 | B1/B4 | 24/16 | 1 | D1 | A | 1.35 | B |
| Comparative | 60 | B1/B2 | 32/8 | 1 | D1 | A | 1.36 | C |
| Example 1 | | | | | | | | |
| Comparative | 60 | B1 | 40 | 1 | D1 | A | 1.36 | C |
| Example 2 | | | | | | | | |
| Comparative | 60 | B2 | 40 | 1 | D1 | A | 1.35 | C |
| Example 3 | | | | | | | | |
| Comparative | 65 | B2 | 35 | 1 | D1 | A | 1.33 | C |
| Example 4 | | | | | | | | |
| Comparative | 70 | B2 | 30 | 1 | D1 | B | 1.32 | C |
| Example 5 | | | | | | | | |
| Comparative | 60 | B2 | 40 | 5 | D1 | A | 1.36 | C |
| Example 6 | | | | | | | | |

According to Table 1, it is shown that when, in a curable composition containing the hollow filler (A), the polymerizable compound (B), the polymerization initiator (C), and the surfactant (D), and not containing an alkali-soluble resin, the polymerizable compound (B) includes a compound (B1) having 5 or more polymerizable functional groups and a compound (B2) having 1 or more and 3 or less polymerizable functional groups, and a ratio (B1/B2) of the mass of the compound (B1) to the mass of the compound (B2) is 0.25 or more and 3 or less, a cured film excellent in heat resistance can be formed. On the other hand, it is shown that when the polymerizable compound (B) includes only one of the compound (B1) having 5 or more polymerizable functional groups and the compound (B2) having 1 or more and 3 or less polymerizable functional groups, or when a ratio (B1/B2) of the mass of the compound (B1) to the mass of the compound (B2) is not 0.25 or more and 3 or less, the cured film thickness has poor heat resistance.

What is claimed is:

1. A curable composition for forming a low refractive index film, the composition comprising a hollow filler (A), a polymerizable compound (B), and a polymerization initiator (C), and not comprising an alkali-soluble resin,
the polymerizable compound (B) comprising a compound (B1) having 5 or more polymerizable functional groups and a compound (B2) having 1 or more and 3 or less polymerizable functional groups,
a ratio (B1/B2) of a mass of the compound (B1) to a mass of the compound (B2) being 0.25 or more and 3 or less.

2. The curable composition for forming a low refractive index film according to claim 1, wherein
the compound (B1) is a compound having 5 or 6 polymerizable functional groups, and
the compound (B2) is a compound having 3 polymerizable functional groups.

3. The curable composition for forming a low refractive index film according to claim 1, wherein a ratio (B1/B2) of a mass of the compound (B1) to a mass of the compound (B2) is 1.25 or more and 2 or less.

4. The curable composition for forming a low refractive index film according to claim 1, further comprising a surfactant (D).

5. The curable composition for forming a low refractive index film according to claim 4, wherein the surfactant (D) comprises a fluorine-based surfactant and/or a silicon-based surfactant.

6. The curable composition for forming a low refractive index film according to claim 1, wherein the hollow filler (A) comprises hollow silica.

7. A low refractive index film comprising a cured product of the curable composition for forming a low refractive index film according to claim 1.

8. An optical device comprising the low refractive index film according to claim 7.

9. A method for producing a low refractive index film, the method comprising forming a coating film of the curable composition for forming a low refractive index film according to claim 1; and
curing the coating film.

10. The method for producing the low refractive index film according to claim 9, wherein the coating film is formed by a spin coating method, a spray coating method, a slit coating method, a bar coating method, or a dip coating method.

11. The method for producing the low refractive index film according to claim 9, wherein the coating film is cured by exposure to light.
